(19) United States
(12) Patent Application Publication
(10) Pub. No.: US 2017/0211769 A1
(43) Pub. Date: Jul. 27, 2017

(54) VEHICLE LAMP DEVICE AND LIGHT-EMITTING MODULE THEREOF

(71) Applicants: LITE-ON ELECTRONICS (GUANGZHOU) LIMITED, GUANGZHOU (CN); LITE-ON TECHNOLOGY CORPORATION, TAIPEI CITY (TW)

(72) Inventors: CHING-TANG FU, TAOYUAN CITY (TW); CHIA-JUNG TSAI, KAOHSIUNG CITY (TW)

(21) Appl. No.: 15/175,113

(22) Filed: Jun. 7, 2016

(30) Foreign Application Priority Data
Jan. 27, 2016 (TW) 105201227

(51) Int. Cl. F21S 8/10; H01L 33/62; H01L 33/48

(52) U.S. Cl. CPC F21S 48/1109; H01L 33/486; H01L 33/62; F21S 48/115

(57) ABSTRACT

Disclosed is a light-emitting module, comprising: a circuit board, a conductive layer, an LED chip, and an adhesive layer. The circuit board comprises a chip-attachment area, the conductive layer being disposed on the chip-attachment area, the LED chip being disposed on the conductive layer and electrically connected to the circuit board through the conductive layer, and the adhesive layer being used for connecting the LED chip to the circuit board, wherein a curing temperature of the adhesive layer is lower than a melting point of the conductive layer. Adopting the aforementioned technical means, the degree of offset in the position of the LED chip after reflow soldering can be greatly reduced. In addition, a vehicle lamp device using the light-emitting module is also provided.

### TECHNICAL FIELD

The present invention relates to a light-emitting module, and more particularly to a light-emitting module for improving the positioning accuracy of LEDs.

### BACKGROUND ART

LEDs have numerous advantages such as long service life, small volume, low power consumption, and have been commonly used in displays or lighting devices. For example, LEDs are used as backlight sources of LCD displays and cell phones or as part of vehicle lamps. Recently, light-emitting modules produced by mounting a plurality of LEDs on a substrate using Surface Mount Technology (SMT) have been continuously developed, and lighting devices (e.g. vehicle lamp devices) equipped with such light-emitting modules are being used more and more as main lighting sources of automobiles.

SMT is a technology that firstly prints a solder paste on a surface of a substrate and places various optical elements or electronic elements (such as LEDs, resistors, capacitors, chips) at corresponding positions where the solder paste was printed, and then the substrate with the plurality of elements is subjected to reflow soldering to cause the elements to be soldered to the substrate and become electrically connected to the substrate. However, the following factors result in the displacement of the elements during the reflow soldering process: 1. tolerances of the elements themselves; 2. alignment tolerances between the elements; 3. mutual pulling forces between the elements and the solder paste generated when the solder paste is melting. Taking LED for example, the offset between a final position and a predetermined position of an LED often exceeds ±100 um (in which the effect of the reflow soldering process has not been considered). Thus, how to overcome the above shortcomings through the improvement in structural design and process technology has become one of the major issues to be solved in the art.

### SUMMARY OF THE INVENTION

In view of the shortcomings in the prior art, an object of the present invention is to provide a light-emitting module which can ensure that the positioning effect of high-precision with an offset below ±25 um is achieved for an LED chip after a reflow soldering process of the LED.

To achieve the above objective, the present invention adopts the following technical solution: a light-emitting module, comprising: a circuit board, a conductive layer, an LED chip, and an adhesive layer for connecting the LED chip to the circuit board. The circuit board comprises a chip-attachment area, the conductive layer being disposed on the chip-attachment area, the LED chip being disposed on the conductive layer and electrically connected to the circuit board through the conductive layer, wherein a curing temperature of the adhesive layer is lower than a melting point of the conductive layer.

In one preferred embodiment of the present invention, the light-emitting module comprises a circuit board, a conductive layer, an LED chip, and an adhesive layer. The circuit board comprises a chip-attachment area, the conductive layer being disposed on the chip-attachment area, the LED chip being disposed on the conductive layer and electrically connected to the circuit board through the conductive layer, and the adhesive layer being cured on the circuit board for connecting the LED chip to the circuit board before the conductive layer is reflow soldered.

In another preferred embodiment of the present invention, the light-emitting module comprises a circuit board, a conductive layer, and an LED chip. The circuit board comprises a chip-attachment area, the conductive layer being disposed on the chip-attachment area, the LED chip being disposed on the conductive layer and electrically connected to the circuit board through the conductive layer, wherein the relative position between the LED chip and the chip-attachment area of the circuit board is fixed by an adhesive layer before the conductive layer is reflow soldered.

The present invention at least has the technical effect that: in a light-emitting module according to the embodiments of the present invention, through the design in which “the LED chip is disposed on the chip-attachment area and is electrically connected to the circuit board through the conductive layer, and the adhesive layer is disposed at the periphery of the chip-attaching area and is in contact with the LED chip, wherein the curing temperature of the adhesive layer is lower than the melting point of the conductive layer” and “the LED chip is disposed on the chip-attachment area and is electrically connected to the circuit board through the conductive dielectric layer, and the LED chip is accurately positioned using an adhesive layer before the LED chip is reflow soldered onto the circuit board through the conductive layer,” the conductive layer in a high-temperature molten state which causes the displacement of the LED chip can be prevented, achieving a precise positioning of the LED chip, further allowing for LED headlamps in high-precision design.

In order to further understand the features and technical content of the present invention, reference is made to the following detailed description and accompanying drawings of the present disclosure. However, the description and accompanying drawings are for illustrative purposes only and is not intended to be a limitation on the scope of the present disclosure.

### BRIEF DESCRIPTION OF DRAWINGS

FIG. 1 is a plan view of a light-emitting module according to a first embodiment of the present invention.

FIG. 2 is a cross-sectional view of an aspect of the light-emitting module according to the first embodiment of the present invention.

FIG. 3 is a cross-sectional view of another aspect of the light-emitting module according to the first embodiment of the present invention.

FIG. 4 is a flow diagram of a computing and positioning process according to the present invention.

FIG. 5 is a schematic view (1) of steps of the computing and positioning process according to the present invention.

FIG. 6 is a schematic view (2) of steps of the computing and positioning process according to the present invention.

FIG. 7 is a schematic view of a front image of an LED chip taken by the computing and positioning process according to the present invention.

FIG. 8 is a schematic view (3) of steps of the computing and positioning process according to the present invention.

FIG. 9 is a schematic view of a back image of the LED chip taken by the computing and positioning process according to the present invention.

FIG. 10 is a schematic view of a vehicle lamp device according to a second embodiment of the present invention.

### DETAILED DESCRIPTION OF EMBODIMENTS

The present invention is mainly directed to structural improvements of an LED light-emitting module which can be applied to vehicle lamps, characterized in that for each SMT element (e.g. SMT type LED element) placed on a circuit board, at least one adhesive layer position where an adhesive layer is to be disposed is preserved at the periphery of a configuration area of the SMT elements, wherein the adhesive layer has a curing temperature lower than the melting point of the solder paste. After being disposed on the adhesive layer position, the adhesive layer is in contact with the SMT elements. With this design, the displacement of the SMT elements due to the melting solder paste during a reflow soldering process can be prevented, achieving the effect of precise positioning of the SMT elements.

Embodiments of a light-emitting module of the present invention are described below. Those skilled in the art can easily understand the advantages and effects of the present invention from the description disclosed herein. The present invention may be implemented as or applied in other different specific embodiments. All details in this description may also be modified or changed based on different ideas and applications without departing from the spirit of the present invention. In addition, the drawings of the present invention are only intended for illustration and are not drawn to scale, that is, actual dimensions of relevant components are not reflected. The following embodiments are used to further describe the technical contents of the present invention in detail and are not intended to limit the technical scope of the present invention in any way.

### First Embodiment

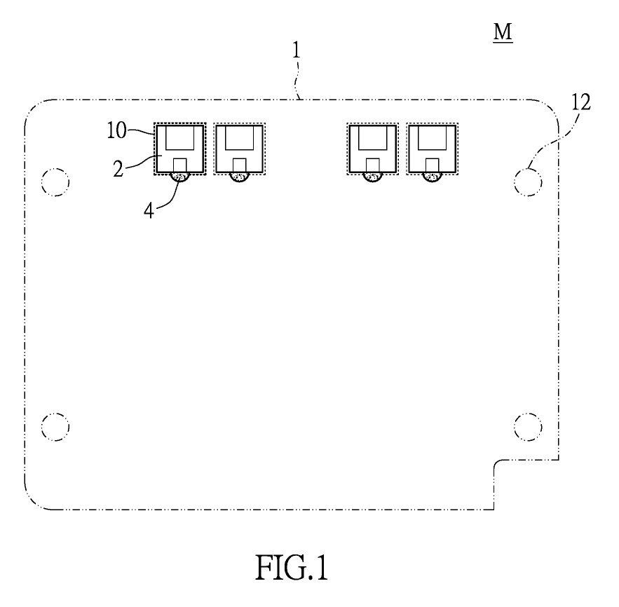

Referring to FIG. 1 to FIG. 3, a light-emitting module M, comprising a circuit board 1, a conductive layer 3, an LED chip 2, and an adhesive layer 4 is provided. Structurally speaking, the circuit board 1 comprises a chip-attachment area 10, the conductive layer 3 being disposed on the chip-attachment area, the LED chip 2 being disposed on the chip-attachment area 10 and electrically connected to the circuit board 1 through the conductive layer 3, the adhesive layer 3 being used for connecting the LED chip 2 to the circuit board 1, wherein a curing temperature of the adhesive layer is lower than a melting point of the conductive layer. Specifically, the conductive layer 3 is formed between the LED chip 2 and the circuit board 1, and the adhesive layer 4 is formed on the periphery of a configuration area of the LED chip 2 so as to fix the relative position between the LED chip 2 and the chip-attachment area 10. In the present embodiment, the circuit board 1 is an LED lamp board, and the circuit board 1 may be a fiberglass PCB, a metal core PCB (MCPCB), or a ceramic substrate, and so on. The chip-attachment area 10 is configured to define a configuration area of the LED chip 2, and a plurality of PCB pads 11 spaced from each other are disposed in the chip-attachment area 10. The positions of the PCB pads 11 are vertically corresponding to the electrodes 21 of the LED chip 2 that are to be placed. The PCB pads 11 are electrically coupled to a control network (not shown) of the circuit board 1, and are also electrically coupled to the electrodes 21 of the LED chip 2 through the conductive layer 3 for driving the LED chip 2 to emit light.

In addition, according to a desired circuit layout, the circuit board 1 may further be configured with electronic components such as transformers, capacitors, resistors, inductors, diodes, integrated circuits (IC), or connectors, and these components may be mounted at suitable engagement positions on the circuit board 1.

The LED chip 2 is an SMT element; namely, the LED chip 2 is mounted on the chip-attachment area 10 of the circuit board 1 using Surface Mount Technology (or SMT). Specifically, the process of placement of the LED chip 2 comprises: printing a conductive layer 3 onto the PCB pads 11 of the chip-attachment area 10 using a screen printer, placing the LED chip 2 onto the conductive layer 3 using an LED mounting apparatus, and then melting the conductive layer 3 by a soldering apparatus (e.g. air reflow soldering oven, nitrogen reflow soldering oven, vapor-phase vacuum soldering device) to cause the LED chip 2 to be soldered to the PCB pads 11.

In order to avoid the pulling effect exerted by the conductive layer 3 in a high-temperature molten state on the LED chip 2 resulting in the displacement of the LED chip 2 from a predetermined position, the present invention is: forming the at least one adhesive layer 4 on at least one point at the periphery of the chip-attachment area 10 to limit the offset of the LED chip 2. For example, two adhesive layers 4 may be formed and in contact with the bottom edges of two adjacent sides of the LED chip 2. The adhesive layers can be formed at the bottom edges of the opposite sides of the LED chip 2. The four adhesive layers 4 may also be formed to be in contact with the bottom edges of all sides of the LED chip 2 at the same time. In other words, there is no limitation on the number of the adhesive layers 4 and the exact location on the periphery of the chip-attachment area 10 at which the adhesive layer 4 is disposed. In addition, a contact point between the adhesive layer 4 and the LED chip 2 may be at any position at a bottom edge of a side of the LED chip 2, and the present invention is not limited thereto. For example, a portion of the adhesive layer 4 may be in contact with a central position of a marginal region on a bottom surface of the LED chip 4, or a portion of the adhesive layer 4 may be in contact with a lower center position on one of the lateral surfaces of the LED chip 2. Further, the position of the adhesive layer 4 is not limited to be at the periphery of the chip-attachment area 10; instead, the adhesive layer 4 may also be formed between the LED chip 2 and the corresponding chip-attachment area 10 according to the requirements of the manufacturing process or product. In addition, the adhesive layer 4 may be substituted with an IR adhesive. However, the present invention is not limited to this example. This invention is to provide an LED module wherein the LED chip 2 is positioned on the periphery of the corresponding chip-attachment area 10 by the adhesive layer 4 before reflow soldering is performed.

Although in the light-emitting module M as shown in FIG. 1, the adhesive layer 4 is disposed at the periphery of the chip-attachment area 10 for effectively fixing the LED chip 2 during reflow soldering, in other aspects of the present embodiment, through the adhesive property of the adhesive layer 4, the same effect may also act on other SMT elements. That is to say, the relative position between the adhesive layer 4 and the other components comprised in the light-emitting module M shown in FIG. 1 is provided for reference and illustration, and is not used to limit the present invention.

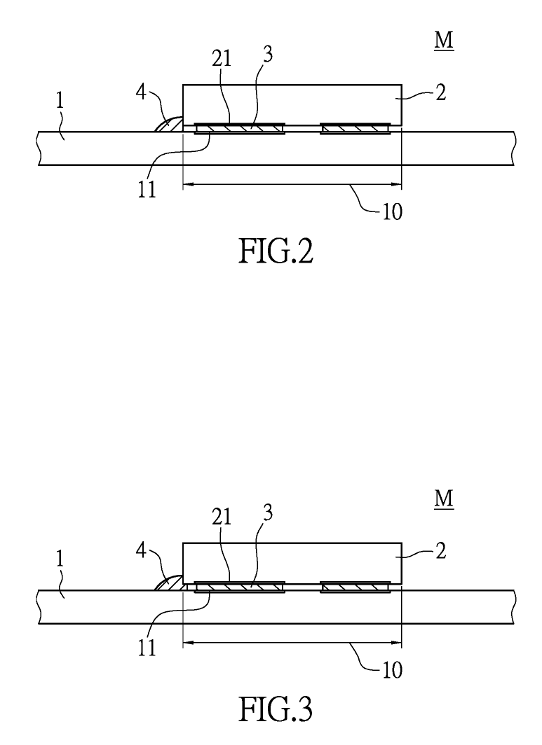

Further, in a preferred embodiment of the present invention, the adhesive layer 4 is an adhesive droplet formed by using a thermosetting material supplying device, and the adhesive layer 4 is slightly in contact with a central position on one bottom edge of one lateral side of the LED chip 2 such that with a limited volume, the adhesive layer 4 can effectively limit the shift (drift) of the LED chip 2 without being affected by the degree of contact between the adhesive layer 4 and the LED chip 2. The expression “slightly in contact with” mentioned herein means that when the adhesive layer 4 is in a semi-cured or cured state, a small portion of the adhesive layer 4 is in contact with any position on the LED chip 2 (as shown in FIG. 2). Alternatively, when the adhesive layer 4 is in a semi-cured or cured state, a small portion of the adhesive layer 4 enters between the LED chip 2 and the circuit board 1 (as shown in FIG. 3), e.g. the adhesive layer 4 may have a first portion formed inside a gap between the LED chip 2 and the circuit board 1 and a second portion connected with the first portion and formed outside the gap, or the first portion of the adhesive layer 4 is in contact with a central position of a marginal region on a bottom surface of the LED chip 2, and the second portion of the adhesive layer 4 is in contact with a lower center position on one of the lateral surfaces of the at least one LED chip 2.

It is to be noted that a material having a curing temperature lower than the melting point of the conductive layer 3 should be selected to be the material of the adhesive layer 4. Therefore, when a reflow soldering process is performed, the adhesive layer 4 can effectively fix the relative position between the LED chip 2 and the circuit board 1 after a heat treatment at a first-stage temperature for thermally curing the adhesive layer 4. The conductive layer 3 can be melted at a second-stage temperature, i.e. the melting point of the conductive layer 3, causing the LED chip 2 to be soldered on the PCB pads 11 of the chip-attachment area 10 after a heat treatment at the second-stage temperature. The second-stage temperature is higher than the first-stage temperature, and thus the adhesive layer 4 will not be softened or melted again during further heating.

In the present embodiment, an epoxy adhesive may be selected to be the material of the adhesive layer 4, and the first-stage temperature corresponding to the epoxy adhesive may be between 90° C. and 150° C. In addition, a solder layer may be selected to be the conductive layer 3, and the second-stage temperature corresponding to the solder layer may be between 217° C. and 230° C. The solder layer may be a tin-silver-copper alloy or a tin-gold alloy, but the present invention is not limited thereto. The adhesive layer 4 can also be a non-conductive layer or a thermosetting adhesive layer; the present invention is not limited thereto. Specifically, any material which has a curing temperature lower than the melting point of the solder may be used to be the adhesive layer 4, in which the adhesive layer 4 will not be softened or melted again from heating after already being cured. In other words, the material of the adhesive layer 4 prevents a cured adhesive layer 4 from being softened or melted when being heated to the melting point of the solder layer. For example, in other aspects of the present embodiment, a tin-gold alloy or a non-conductive adhesive may also be selected to be the adhesive layer 4.

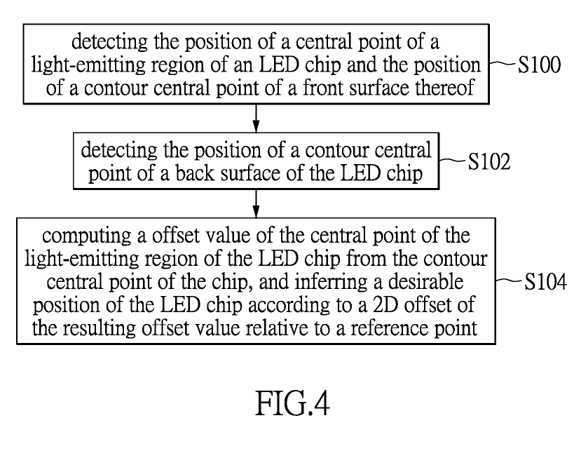

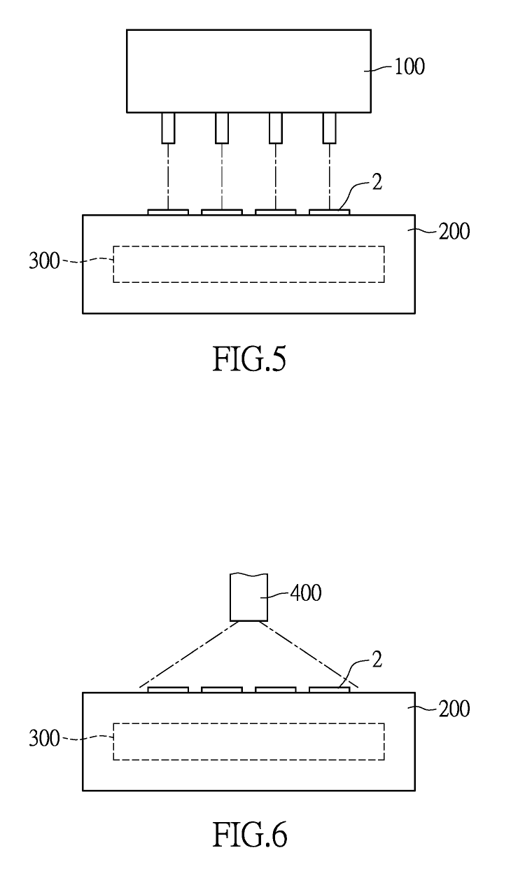

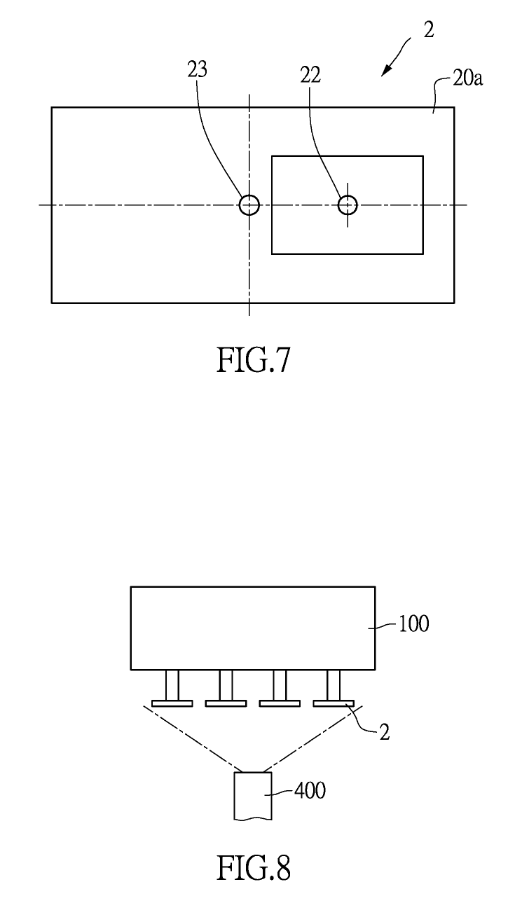

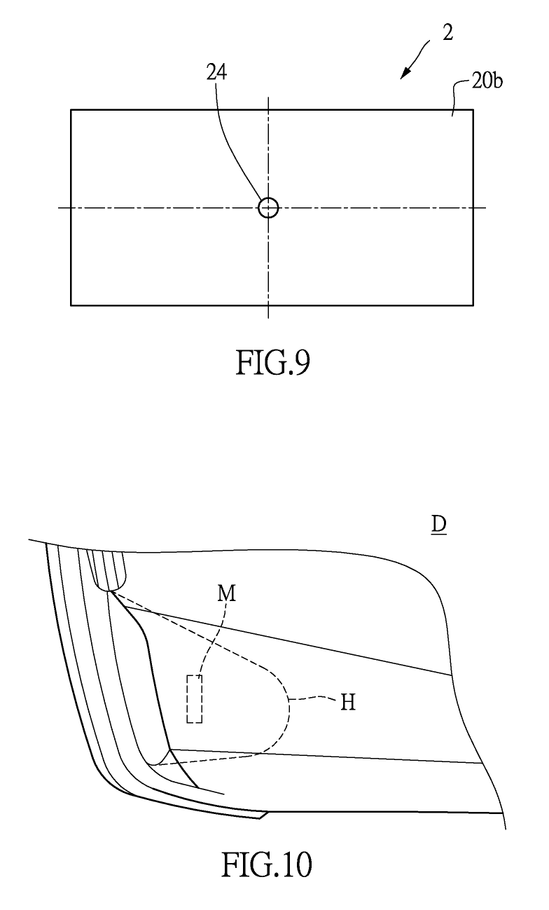

Referring to FIG. 1, and FIG. 4 to FIG. 9, it is also to be noted that normally, tolerances are assigned to mechanical and electronic components such as the circuit board 1 and the LED chip 2, and in order to reduce or eliminate the tolerance of each LED chip 2 or the circuit board 1 itself and the alignment tolerance between the LED chip 2 and the circuit board 1 to achieve precise positioning of the LED chip 2 relative to the chip-attachment area 10, the present invention adopts the following computing and positioning process: step S100, detecting the position of a central point 22 of a light-emitting region of an LED chip 2 and the position of a contour central point 23 of a front surface 20a thereof; step S102, detecting the position of a contour central point 24 of a back surface 20b of the LED chip 2; step S104, computing an offset value of the central point 22 of the light-emitting region of the LED chip 2 from the contour central point 23 of the front surface 20a of the LED chip 2, and inferring a desirable position of the LED chip 2 according to the resulting offset value and a 2D offset of the LED chip 2 relative to the contour central point 24 as a reference point.

In implementing the step 100, as shown in FIG. 5 to FIG. 7, a plurality of LED chips 2 are firstly transferred using a robotic arm 100 from a feeder to a bearing platform 200, wherein the bearing platform 200 is provided with at least one magnetic attraction or vacuum suction device and a light emitting device 300 for generating a magnetic force or vacuum suction force and providing an element backlight source so that the LED chips 2 can be securely attached to the bearing platform 200; and then, a front image of the LED chips 2 are acquired using an optical locating device 400 (e.g. CCD camera), and the position of a central point 22 of a light-emitting region of each LED chip 2 and the position of a contour central point 23 of a front surface 20a thereof are identified, the information of which is then converted into a first electrical signal to be transmitted to a processing unit.

In implementing the step S102, as shown in FIG. 8, the LED chips 2 are suctioned off the bearing platform 200 using the robotic arm 100, and then a back image of the LED chips 2 is acquired using the optical locating device 400 (e.g. CCD camera), and then the position of a contour central point 24 of a back surface 20b of each LED chip 2 is identified, the information of which is then converted into a second electrical signal to be transmitted to the processing unit.

In implementing the step S104, the offset value of the central point of the light-emitting region of each LED chip 2 from the contour central point of the chip may be calculated by the processing unit according to the first and second electrical signals, and with positioning holes 12 of the circuit board 1 as reference points, the robotic arm 100 is controlled to accurately place the LED chips 2 at desired positions on the circuit board 1 respectively. That is to say, as shown in FIG. 1, the positioning holes 12 are holes on the circuit board 1 passing therethrough and acting as reference points spatially corresponding to the chip-attachment area.

### Second Embodiment

Referring to FIG. 1 and FIG. 10, a second embodiment of the present invention further provides a vehicle lamp device D (e.g. LED headlamp), mainly comprising a light-emitting module M and a vehicle lamp housing H, wherein the light-emitting module M is mounted in the vehicle lamp housing H. Please refer to the first embodiment for the details concerning the components of the light-emitting module M and the functionality thereof, which will not be described again hereinafter.

### [Possible Effects of the Embodiments]

In the light-emitting module according to the embodiment of the present disclosure, through the design in which “the LED chip is disposed on the chip-attachment area and is electrically connected to the circuit board through the conductive layer, and the adhesive layer is disposed on at least one point at the periphery of the chip-attachment area and is in contact with the LED chip, wherein the curing temperature of the adhesive layer is lower than the melting point of the conductive layer” and “the LED chip is disposed on the chip-attachment area and is electrically connected to the circuit board through the conductive layer, and the LED chip is accurately positioned using an adhesive layer before the LED chip is reflow soldered on the circuit board through the conductive layer.” When the LED chip is reflow soldered, the displacement of the LED chip is restricted since the adhesive layer (various adhesives) can limit the shift of the LED chip, and also the adhesive layer (various adhesives) will not be softened or melted from being heated to the melting temperature of the conductive layer (i.e. the solder layer.) The precise positioning of the LED chip with an offset less than ±25 um can thereby be achieved. In sum, the vehicle lamp device using the light-emitting module provided in the embodiment of the present invention can meet the requirements of future LED headlamps for high-precision design, and thus the vehicle lamp device utilizing the light-emitting module of the present invention possesses enhanced competitive advantage in the market.

The description above is only embodiments of the present invention and is not intended to limit the scope of the present disclosure. Equivalent substitutions of various changes and adjustments made by any of those skilled in the art without departing from the spirit and scope of the present invention fall within the scope of the present invention.

1. A light-emitting module, comprising:
a circuit board, comprising a chip-attachment area;
a conductive layer, disposed on the chip-attachment area,
an LED chip, disposed on the conductive layer and electrically connected to the circuit board through the conductive layer; and
an adhesive layer, for connecting the LED chip to the circuit board, wherein a curing temperature of the adhesive layer is lower than a melting point of the conductive layer.

2. The light-emitting module of claim 1, wherein the adhesive layer is disposed on a periphery of the chip-attachment area so as to fix the relative position between the LED chip and the chip-attachment area of the circuit board.

3. The light-emitting module of claim 1, wherein the curing temperature of the adhesive layer is approximately between 90° C. to 150° C., and the melting point of the conductive layer is approximately between 217° C. to 230° C.

4. The light-emitting module of claim 1, wherein the conductive layer is a solder paste layer, and the adhesive layer is one of an epoxy adhesive layer, a non-conductive layer and a thermosetting adhesive layer.

5. The light-emitting module of claim 1, wherein a material of the conductive layer is selected from one of a tin-silver-copper alloy and a tin-gold alloy.

6. The light-emitting module of claim 1, wherein a portion of the adhesive layer is disposed between the LED chip and the circuit board.

7. The light-emitting module of claim 1, wherein the circuit board further comprises a reference point corresponding to the chip-attachment area.

8. The light-emitting module of claim 7, wherein the reference point is a positioning hole passing through the circuit board.

9. The light-emitting module of claim 1, wherein a portion of the adhesive layer is in contact with a central position of a marginal region on a bottom surface of the LED chip.

10. The light-emitting module of claim 1, wherein a portion of the adhesive layer is in contact with a lower center position on one of the lateral surfaces of the LED chip.

11. The light-emitting module of claim 1, wherein the adhesive layer has a first portion formed inside a gap between the LED chip and the circuit board and a second portion connected with the first portion and formed outside the gap.

12. The light-emitting module of claim 11, wherein the first portion of the adhesive layer is in contact with a central position of a marginal region on a bottom surface of the LED chip, and the second portion of the adhesive layer is in contact with a lower center position on one of the lateral surfaces of the at least one LED chip.

13. The light-emitting module of claim 1, wherein the light-emitting module is applied to a vehicle lamp device.

14. A light-emitting module, comprising:
a circuit board, comprising a chip-attachment area;
a conductive layer, disposed on the chip-attachment area;
an LED chip, disposed on the conductive layer and electrically connected to the circuit board through the conductive layer; and
an adhesive layer, cured on the circuit board for connecting the LED chip to the circuit board before the conductive layer is reflow soldered.

15. A light-emitting module, comprising:
a circuit board, comprising a chip-attachment area;
a conductive layer, disposed on the chip-attachment area, and
an LED chip, disposed on the conductive layer and electrically connected to the circuit board through the conductive layer;
wherein the relative position between the LED chip and the chip-attachment area of the circuit board is fixed by an adhesive layer before the conductive layer is reflow soldered.

16. (canceled)
